(19) United States
(12) Patent Application Publication
(10) Pub. No.: US 2009/0205695 A1
(43) Pub. Date: Aug. 20, 2009

(54) Energy Conversion Device

(75) Inventor: Tarek Makansi, Tucson, AZ (US)

Correspondence Address: HAYES SOLOWAY P.C., 3450 E. SUNRISE DRIVE, SUITE 140, TUCSON, AZ, 85718, US

(73) Assignee: TEMPRONICS, INC., Tucson, AZ (US)

(21) Appl. No.: 12/367,965

(22) Filed: Feb. 9, 2009

Related U.S. Application Data
(60) Provisional application No. 61/065,915, filed on Feb. 15, 2008.

(51) Int. Cl. H01L 35/34; H01L 35/20; H01L 35/16

(52) U.S. Cl. 136/201; 136/240; 136/238; 136/239

(57) ABSTRACT

An improved design for maintaining nanometer separation between electrodes in tunneling, thermo-tunneling, diode, thermionic, thermoelectric, thermo-photovoltaic and other devices is disclosed. At least one electrode is of a curved shape. All embodiments reduce the thermal conduction between the two electrodes when compared to the prior art. Some embodiments provide a large tunneling area surrounding a small contact area. Other embodiments remove the contact area completely. The end result is an electronic device that maintains two closely spaced parallel electrodes in stable equilibrium with a nanometer gap there-between over a large area in a simple configuration for simplified manufacturability and use to convert heat to electricity or electricity to cooling.

### CROSS REFERENCE TO RELATED APPLICATION

This application claims priority from U.S. Provisional Application Ser. No. 61/065,915, filed Feb. 15, 2008, the contents of which are incorporated by reference.

### BACKGROUND

The present invention pertains to diode, thermionic, tunneling, and other devices that are designed to have very small spacing between electrodes and in some cases also require thermal isolation between electrodes. The invention may be applied to thermo-tunneling generators and heat pumps, and can be applied to similar systems using thermionic and thermoelectric methods. These thermo-tunneling generators and heat pumps convert thermal energy into electrical energy and can operate in reverse to provide refrigeration. The invention may also be applied to any device that requires close, parallel spacing of two electrodes with a voltage applied or generated between them.

The phenomenon of high-energy electron flow from one conductor (emitter) to another conductor (collector) has been used in many electronic devices and for a variety of purposes. For example, vacuum-tube diodes were implemented this way, and the physical phenomenon was called thermionic emission. Because of the limitations imposed by the relatively large physical spacing available, these diodes needed to operate at a very high temperature (greater than 1000 degrees Kelvin). The hot electrode needed to be very hot for the electrons to gain enough energy to travel the large distance to the collector and overcome the high quantum barrier. Nevertheless, the vacuum tube permitted electronic diodes and later amplifiers to be built. Over time, these devices were optimized, by using alkali metals, like cesium, or oxides to coat the electrodes, in an effort to reduce the operating temperature. Although the temperatures for thermionic generation are still much higher than room temperature, this method of power generation has utility for conversion of heat from combustion or from solar concentrators to electricity.

Later, it was discovered that if the emitter and the collector were very close to each other, on the order of atomic distances like 2 to 20 nanometers, then the electrons could flow at much lower temperatures, even at room temperature. At this small spacing, the electron clouds of the atoms of the two electrodes are so close that hot electrons actually flow from the emitter cloud to the collector cloud without physical conduction. This type of current flow when the electron clouds are intersecting, but the electrodes are not physically touching, is called tunneling. The scanning tunneling microscope, for example, uses a pointed, conducting stylus that is brought very close to a conducting surface, and the atomic contours of this surface can be mapped out by plotting the electrical current flow as the stylus is scanned across the surface. U.S. Pat. No. 4,343,993 (Binnig, et al.) teaches such a method applied to scanning tunneling microscopy.

It has been known in the industry that if such atomic separations could be maintained over a large area (one square centimeter or even one square millimeter, for example), then a significant amount of heat could be converted to electricity by a single diode-like device and these devices would have utility as refrigerators or in recovering wasted heat energy from a variety of sources. See Efficiency of Refrigeration using Thermotunneling and Thermionic Emission in a Vacuum. Use of Nanometer Scale Design, by Y. Hishinuna, T. H. Geballe, B. Y. Moyzhes, and T. W. Kenny, Applied Physics Letters, Volume 78, No. 17, 23 Apr. 2001; Vacuum Thermionic Refrigeration with a Semiconductor Heterojunction Structure, by Y. Hishinuna, T. H. Geballe, B. Y. Moyzhes, Applied Physics Letters, Volume 81, No. 22, 25 Nov. 2002; and Measurements of Cooling by Room Temperature Thermionic Emission Across a Nanometer Gap, by Y. Hishinuma, T. H. Geballe, B. Y. Moyzhes, and T. W. Kenny, Journal of Applied Physics, Volume 94, No. 7, 1 Oct. 2003. The spacing between the electrodes must be small enough to allow the “hot” electrons (those electrons with energy above the Fermi level) to flow, but not so close as to allow normal conduction (flow of electrons at or below the Fermi level). In some cases, the vacuum gap might be used to minimize thermal conductance by lattice phonon vibration and the filtering of the hot electrons can take place in a semiconductor or thermoelectric material adjacent to the gap as exemplified in International PCT PCT/US07/77042 by the same inventor. There is a workable range of separation distance between 0.5 and 20 nanometers that allows thousands of watts per square centimeter of conversion from electricity to refrigeration. See Efficiency of Refrigeration using Thermotunneling and Thermionic Emission in a Vacuum. Use of Nanometer Scale Design, by Y. Hishinuna, T. H. Geballe, B. Y. Moyzhes, and T. W. Kenny, Applied Physics Letters, Volume 78, No. 17, 23 Apr. 2001. These references also suggest the advantage of a coating or monolayer of an alkali metal, or other material, on the emitting electrode in order to achieve a low work function in the transfer of electrons from one electrode to the other. This coating or monolayer further reduces the operating temperature and increases the efficiency of conversion for those configurations without a separate means for electron filtering.

Mahan showed that the theoretical efficiency of a thermionic refrigerator, using electrodes with a work function of 0.7 eV and a cold temperature of 500 K, is higher than 80% of Carnot efficiency. See Thermionic Refrigeration, By G. D. Mahan, Journal of Applied Physics, Volume 76, No. 7, 1 Oct. 1994. Also, see Multilayer Thermionic Refrigerator, By G. D. Mahan, J. A. Sofao and M. Bartkoiwak, Journal of Applied Physics, Volume 83, No. 9, 1 May 1998. By analogy a conversion efficiency of the electron tunneling process is expected to also be a high fraction of Carnot efficiency. Carnot efficiency presents an upper bound on the achievable efficiency of thermal energy conversion.

The maintenance of separation of the electrodes at atomic dimensions over a large area has been the single, most significant challenge in building devices that can remove heat from a conductor. The scanning tunneling microscope, for example, requires a special lab environment that is vibration free, and its operation is limited to an area of a few square nanometers. Measurements of cooling in a working apparatus have been limited to an area of a few square nanometers. See Measurements of Cooling by Room Temperature Thermionic Emission Across a Nanometer Gap, by Y. Hishinuma, T. H. Geballe, B. Y. Moyzhes, and T. W. Kenny, Journal of Applied Physics, Volume 94, No. 7, 1 Oct. 2003.

More recently, in PCT/US07/77042, devices have been built that achieve much larger amounts of energy conversion of milliwatts or fractions of watt using a pair of bimetal electrodes tested in a vacuum chamber. The device described in this patent application, by the same inventor, has been used successfully to form nanometer gaps in a bell jar vacuum apparatus such that many materials on either side of the gap can be explored and measured. In addition, a fully packaged device with the successful gap-forming method of PCT/US07/77042 will be presented here, and this device can serve as a fully functional energy conversion product usable outside of a vacuum apparatus.

Hence, there remains a need for a fully packaged device, which cost-effectively and efficiently converts heat energy into electrical energy in a package that is convenient to use for both the heat source as input and the electrical circuits needing power as output. Abundant sources of heat, including waste heat, could easily become sources of electricity. Examples where employing such devices would help the environment, save money, or both, include:

(1) Conversion of the sun's heat and light into electricity more cost effectively than photovoltaic devices currently used.

(2) Recovery of the heat generated by an internal combustion engine, like that used in automobile, back into useful motion. Some automobiles available today, called hybrid gas-electric automobiles, can use either electrical power or internal combustion to create motion. About 75% of the energy in gasoline is converted to waste heat in today's internal combustion engine. A tunneling conversion device could recover much of that heat energy from the engine of a hybrid automobile and put it into the battery for later use. U.S. Pat. No. 6,651,760 (Cox, et al.) teaches a method of converting the heat from a combustion chamber and storing or converting the energy to motion.

(3) Reducing the need for noxious gases to enter the atmosphere. The more energy-efficient hybrid automobile is a clear example where noxious exhaust gases escaping into the atmosphere can be reduced. A device that converts engine and exhaust heat of the hybrid engine and then stores or produces electricity in the hybrid battery would further increase the efficiency of the hybrid automobile and reduce the need to expel noxious gases. Coolants used in refrigeration are other examples of noxious gases that are necessary to remove heat, and tunneling conversion devices could reduce the need for emission of noxious gases.

(4) Recovery of heat energy at a time when it is available, then storing it as chemical energy in a battery, and then re-using it at a time when it is not available. Tunneling conversion devices could convert the sun's energy to electricity during the day and then store it in a battery. During the night, the stored battery power could be used to produce electricity.

(5) Power generation from geothermal energy. Heat exists in many places on the surface of the earth, and is virtually infinitely abundant deep inside the earth. An efficient tunneling conversion device could tap this supply of energy.

(6) Production of refrigeration by compact, silent and stationary solid state devices, where such a tunneling device could provide cooling for air conditioners or refrigeration to replace the need for bulky pneumatic machinery and compressors.

(7) Power generation from body heat. The human body generates about 100 watts of heat, and this heat can be converted to useful electrical power for handheld products like cell phones, cordless phones, music players, personal digital assistants, and flashlights. A thermal conversion device as presented in this disclosure can generate sufficient power to operate or charge the batteries for these handheld products from heat applied through partial contact with the body.

(8) Electrical power from burning fuel. A wood stove generates tens of thousands of watts of heat. Such a tunneling device could generate one or two kilowatts from that heat which is enough to power a typical home's electric appliances. Similar applications are possible by burning other fuels such as natural gas, coal, and others. Then homes in remote areas may not require connection to the power grid or noisy electrical generators to have modern conveniences.

The challenge in bringing two parallel electrodes together within less than 20.0 nanometer separation gap and the proposed solution by this inventor and others is well described in PCT/US07/77042 and in “Analysis of nanometer vacuum gap formation in thermo-tunneling devices”, by E T Enikov and T Makansi, Nanotechnology Journal, 2008. Here, we will focus on a fully packaged device with its own vacuum chamber that can be manufactured at a low cost for mass production and competitively priced relative to compressors, turbines, and electrical generators. This device contains within it the gap-forming bimetal electrode design summarized in PCT/US07/77042.

### PRIOR ART

The art of separating two conductors by about 2.0 to 20.0 nanometers over a square centimeter area has been advanced by the use of an array of feedback control systems that are very precise over these distances. A control system includes a feedback means for measuring the actual separation, comparing that to the desired separation, and then a moving means for bringing the elements either closer or further away in order to maintain the desired separation. The feedback means can measure the capacitance between the two electrodes, which increases as the separation is reduced. The moving means for these dimensions is, in the state of the art, an actuator that produces motion through piezoelectric, magnetostriction, or electrostriction phenomena. U.S. Pat. No. 6,720,704 (Tavkhelidze, et al.) and U.S. Pat. No. 7,253,549 (Tavkhelidze, et al.) and US Patent Application No. 2007/0033782 (Taliashvili et al.) describes such a design that includes shaping one surface using the other and then using feedback control systems to finalize the parallelism prior to use. Because of the elaborate processes involved in shaping one surface against the other and the use of multiple feedback control systems to maintain parallelism, this design approach is a challenge to manufacture at a low cost.

Other methods have been documented in U.S. Pat. No. 6,774,003 (Tavkhelidze, et al.), and U.S. Pat. No. 7,140,102 (Taliashvili, et al.), and US Patent Applications 2002/0170172 (Tavkhelidze, et al.), 2006/0038290 (Tavkhelidze, et al.), and 2001/0046749 (Tavkhelidze, et al.) that involve the insertion of a “sacrificial layer” between the electrodes during fabrication. The sacrificial layer is then evaporated to produce a gap between the electrodes that is close to the desired spacing of 2 to 20 nanometers. These three methods are either susceptible to post-fabrication fluctuations due to warping or thermal expansion differences between the electrodes, or require the array of actuators to compensate for these fluctuations, as described in US Patent Application Nos. 2005/0189871 (Tavkhelidze, et al.) and 2007/0056623 (Tavkhelidze, et al.). Another method of achieving and maintaining the desired spacing over time is documented in U.S. Pat. No. 6,876,123 (Martinovsky, et al.) and U.S. Pat. No. 7,305,839 (Weaver) and U.S. Pat. No. 6,946,596 (Kucherov, et al.) in US Patent Application Nos. 2004/0050415, 2006/0192196 (Tavkhelidze, et al.), 2003/0042819 (Martinovsky, et al.), 2006/0207643 (Weaver et al.), 2007/0069357 (Weaver et al.), and 2008/0042163 (Weaver) through the use of dielectric spacers that hold the spacing of a flexible electrode much like the way poles hold up a tent. One disadvantage of these dielectric spacers is that they conduct heat from one electrode to the other, reducing the efficiency of the conversion process. Another disadvantage of this method is that the flexible electrodes can stretch or deform between the spacers over time in the presence of the large electrostatic forces and migrate slowly toward a spacing that permits conduction rather than tunneling or thermionic emission. Some of the challenges of forming a nanometer gap with these methods is summarized in “Thermotunneling Based Cooling Systems for High Efficiency Buildings”, by Marco Aimi, Mehmet Arik, James Bray, Thomas Gorezyca, Darryl Michael, and Stan Weaver, General Electric Global Research Center, DOE Report Identifier DE-FC26-04NT42324, 2007.

Another method for achieving a desired vacuum spacing between electrodes is reveled in US Patent Application Nos. 2004/0195934 (Tanielian), 2006/0162761 (Tanielian), 2007/0023077 (Tanielian), 2007/0137687 (Tanielian), and 2008/0155981 (Tanielian) wherein small voids are created at the interface of two bonded wafers. These voids are small enough to allow thermo-tunneling of electrons across a gap of a few nanometers. Although these gaps can support thermo-tunneling, unwanted thermal conduction takes place around the gaps, and the uniformity of the electrode spacing is difficult to control.

Yet another method for achieving a thermo-tunneling gap is by having the facing surfaces of two wafers be in contact, then using actuators to pull them apart by a few nanometers, as described in U.S. Patent Application 2006/0000226. Although this method can produce a thermo-tunneling gap, this method suffers from the cost of multiple actuators and the thermal conduction between wafers outside of the gap area.

### SUMMARY OF THE INVENTION

The present disclosure provides improvements in the packaging, fabrication, and more specific implementation detail of the gap-forming designs described in PCT/US07/77042. Four package design approaches are presented, each trading off cost and reliability uniquely. The first and preferred package design uses flexible glass and flexible silicon to serve simultaneously as the vacuum wall, the electrode substrate, and optionally the circuit board for interconnect. The second package design uses all glass substrates with metal inserts. The third package design employs a flexible plastic material that is a vacuum-compatible offering lower cost, but less reliability due to plastic out-gassing, lower wall rigidity, and some porosity. The fourth package design employs a thick glass wall that is not flexible and hence the gap-forming mechanism is less disturbed by external vibration or shock. However, this design is more costly to manufacture.

For each of the four designs, two embodiments are possible. In one embodiment, each tunneling junction has its own vacuum chamber, and a separate connector is required to provide the interconnecting of multiple junctions. In the second embodiment, multiple junctions share a vacuum chamber with the interconnecting also contained within. Without limitation, the diagrams will show the multiple junction embodiments of which the single junction embodiment is a subset.

A surface roughness of less than 1.0 nanometer can be achieved by any of several techniques known to the industry. Even though silicon and glass wafers are routinely polished to sub-nanometer roughness, the deposition of metal films creates additional roughness from nucleation and grain formation. This surface roughness can then be removed by (1) using a post-polishing process such as chemical mechanical polish called CMP, (2) cooling the substrate during deposition to prevent or minimize grain formation, or (3) pressing the surface against a known smooth surface such as that of a raw wafer. These and other polishing techniques are readily available in the industry for achieving less than 1.0 nanometers surface roughness on metals, semiconductors, and other materials.

Other systems, devices, features and advantages of the disclosed device and process will be or become apparent to one with skill in the art upon examination of the following drawings and detailed description. It is intended that all additional systems, devices, features, and advantages be included within this description, be within the scope of the present invention, and be protected by the accompanying claims.

### BRIEF DESCRIPTION OF THE DRAWINGS

Many aspects of the disclosed device and process can be better understood with reference to the attached drawings. The components in the drawings are not necessarily to scale, emphasis instead being placed upon clearly illustrating the principles of the present invention. Moreover, in the drawings, like reference numerals do not need corresponding parts throughout the several views. While exemplary embodiments are disclosed in connection with the drawings, there is no intent to limit the disclosure to the embodiments disclosed herein. On the contrary the intent is to cover all alternatives, modifications and equivalents.

FIG. 1a and FIG. 1b illustrate a single junction of the present invention with one curved electrode and one flat electrode with contact in the center; FIG. 1a is a profile view, and FIG. 1b illustrates regions of the interior surface;

FIG. 2a and FIG. 2b illustrate a single junction, but with corner posts added in order for the center contact to be replaced with a nanometer gap under certain operating conditions. FIG. 2a is a profile view, and FIG. 2b illustrates regions of the interior surface;

FIG. 3a shows how the junction of FIGS. 1a and 1b or FIGS. 2a and 2b can be used to provide refrigeration upon electrical activation, and FIG. 3b alternatively shows how these same devices can be used to convert heat to electricity’

FIG. 4a through FIG. 4d show how a plurality of junctions connected in series electrically can come together in a single vacuum package where silicon serves as the flexible substrates as well as a partial vacuum wall, and flexible glass serves as a thermal isolator as well as the remaining vacuum wall;

FIG. 5a and FIG. 5b show more detail of the device of FIG. 4 in a profile view including the stack of films to create the thermoelectric junctions and to connect them together;

FIG. 6 shows an alternative embodiment to FIG. 5a and FIG. 5b using flexible glass as the substrates and the vacuum walls, and with metal inserts in the glass to improve thermal conduction away from the junction;

FIG. 7 shows another alternative embodiment to FIG. 5a and FIG. 5b using a flexible, vacuum-compatible plastic as the vacuum wall and separate silicon dice as the substrates;

FIG. 8a and FIG, 8b show another alternative embodiment to FIG. 5a and FIG. 5b using rigid glass as the vacuum wall and flexible silicon as the substrate. FIG. 9a illustrates an arrangement for decreasing the curvature in the center of a bimetal arrangement (which in turn increases the active area of tunneling) by removing some material, which may be applied to any or all of the embodiments of FIG. 1 through FIG. 8;

FIG. 9b plots radius of curvature and radius of hole;

FIG. 10a and FIG. 10b show other geometric configurations that are analogous to FIG. 1a and FIG. 1b and FIG. 2a and FIG. 2b in providing a small contact area combined with a larger tunneling area for electron flow;

FIG. 11 illustrates a device similar to that shown in FIG. 2a; and

FIG. 12 is a plot of Peltier coefficient against Chip Temperature.

### THEORY OF THERMOELECTRIC DEVICE PERFORMANCE

The figure of merit for a thermoelectric device is

ZT=═²T/KR

α is the Seebeck coefficient in volts per degree of temperature difference, T is the temperature in Kelvin, K is the thermal conduction in watts per degree of temperature difference, and R is the electrical resistance. The electrical resistance R can further be expressed as

R=ρL/Aₑ

ρ is the electrical resistivity of the thermoelectric material, L is the length that the electrons must travel in this material, and Aₑ is the cross-sectional area of the electron flow. The thermal conduction K can be further expressed as

K=(κₑAₑ+κ_{|}A_{|})/L

L is again the length of the material. Two mechanisms exist for heat conduction in a metal or semiconductor, one due to electron flow and the other due to phonon flow. The heat conduction due to phonon flow is also called lattice thermal conduction. In this equation, κₑ is the thermal conductivity component due to electrons and Aₑ is the cross-sectional area over which electrons can flow, as before. κ_{|} is component of thermal conductivity due to phonons and A_{|} is the cross-sectional area through which phonons can flow. Substituting the expressions for R and K into the formula for ZT yields the following equation:

ZT=α²TAₑ/[ρ(κₑAₑ+κ_{|}A_{|})]

In thermoelectric materials and for traditional thermoelectric devices Aₑ=A_{|}, and hence KR=κρ.

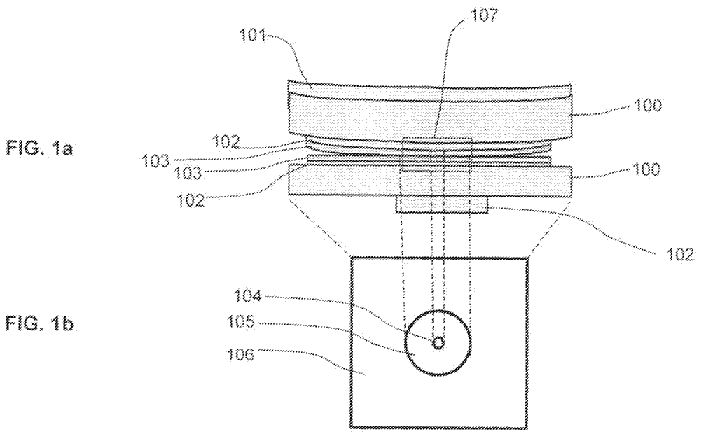

In a thermoelectric device, it is desirable to minimize electrical resistance to reduce electrical losses, which affects efficiency. It is also desirable to minimize thermal conduction so that losses due to heat backflow from the hot side to the cold side are minimized. A traditional thermoelectric device only allows electrons to conduct through the thermoelectrically active material. In one embodiment of this invention illustrated in FIG. 1a and FIG. 1b, electrons and phonons conduct though a portion of the cross-sectional area, but only electrons are able to tunnel through a much larger area. By having a larger area for electron flow than for phonon flow, the performance of the device can be increased significantly. An important part of this invention is a device wherein A_{|} can be less than Aₑ and this difference leads to a higher ZT and a higher efficiency and performance.

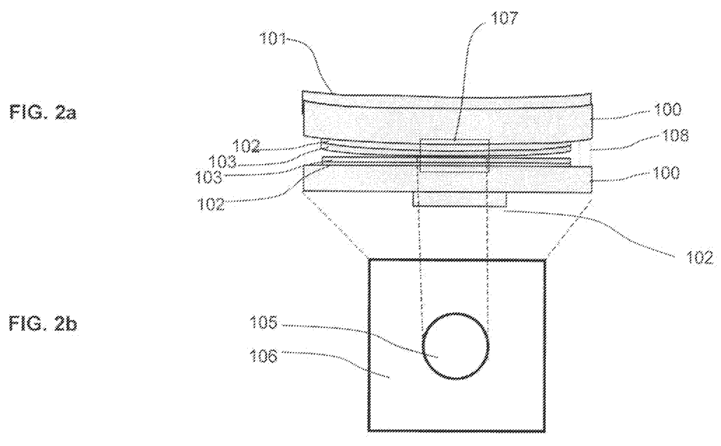

In another embodiment of this invention illustrated in FIG. 2, no phonon transfer is possible, but electrons are still able to tunnel over the entire cross-sectional area, increasing performance and efficiency even further than illustrated in FIG. 1a and FIG 1b. In this case A_{|} is zero, leading to an even higher ZT, efficiency, and performance.

### DETAILED DESCRIPTION OF THE EXEMPLARY EMBODIMENTS

Referring more specifically to the drawings in which like reference numerals refer to like elements throughout the several views, exemplary embodiments of the device and process of the present disclosure are illustrated in FIGS. 1-12.

In FIG. 1a, two electrodes are shown, one curved and the other essentially flat. A piece of single-crystal silicon 100 serves as the substrate, and this substrate is highly doped to levels of 0.001 to 0.01 ohm-cm to allow electrical conductivity from top to bottom. Without limitation, other semiconductors could be used for substrate 100 such as silicon carbide, germanium, and gallium arsenide. Both types of metal layers 101 and 102 serve to spread the electrical current allowing this current to flow across the entire area of the silicon substrate 100, thereby reducing resistance of current flow from the top of the device to the bottom. Metal layer 101 is thicker, or laterally larger, or both thicker and laterally larger than metal layer 102. Layer 103 is the thermoelectrically active material. Depositing metal layer 101 on or otherwise adhering it to silicon substrate 100 at an elevated temperature forms the curved upper electrode. As the pair of layers 100 and 101 cool down to room temperature after deposition or adhesion, the greater thermal contraction of metal 101 relative to silicon 100 introduces mechanical stresses that give rise the curved shape shown. This curvature occurs in both lateral dimensions, making the curved shape a dome, although FIG. 1a shows only a profile view. Without limitation, other arrangements for achieving a curved surface are included such as micromachining or pulling forces of an interior vacuum cavity.

In operation, the two electrodes in FIG. 1a are spring loaded to push against each other, and the apparatus in this figure is placed in a vacuum chamber. To activate the device for cooling, a voltage is applied between the very top 101 and very bottom 102 metal layers 102. This voltage gives rise to a current flow through the thermoelectrically active layer 103 and this current moves heat either in the same direction of the current if the material 103 is p-type or in the opposite direction as the current if material 103 is n-type material. To activate the device for power generation, heat is applied to the lower electrode, giving rise to a temperature gradient between the lower and upper electrodes and this gradient produces a voltage, called the Seebeck voltage, between the top and bottom electrodes.

The central portion 107 of the invention illustrated in FIG. 1a is similar to a traditional thermoelectric device with one unique exception, which is a key aspect of this invention. In a standard thermoelectric device, active layer 103 in central portion 107 would be continuous from top to bottom. In the invention device, active layer 103 has some continuity vertically through a contact area 104 illustrated in FIG. 1b. In this contact area 104, both electrons and phonons can conduct heat, and electrons can conduct electricity. The area 105 surrounding the contact area 104 is of particular interest. The geometry of the device is designed such that electrons are able to tunnel in non-contact vacuum-gap area 105, but phonons are not able to flow at all due to interruption of the crystal lattice with a vacuum layer. Hence the area of electron flow 105 is larger than the area of phonon flow 104. Area 106 is the total area of the silicon substrate, which may include an area where neither electrons nor phonons can flow because the vacuum gap is too large for electrons to tunnel.

To estimate the figure of merit ZT improvement of the device of FIG. 1a, the active layer material 103 will be assumed to be Bi₂Te₃, the most widely used thermoelectric material. Furthermore, the operating temperature T will be assumed to be room temperature or 300 Kelvin. The following parameter values are well published for this material: α=260 microvolts per degree Kelvin, ρ=0.001 ohm-centimeter, κₑ=0.4 watts/meter-degree Kelvin, κ_{|}=1.6 watts/meter-degree Kelvin. For a traditional thermoelectric device, Aₑ=A_{|}. Substituting these values into the formula for ZT

ZT=α²TAₑ/[ρ(κₑAₑ+κ_{|}A_{|})]

The formula for ZT computes to a value of 1.04, which is the published and commonly cited ZT performance for Bi₂Te₃ devices when Aₑ=A_{|}. If we now refer to FIG. 1a and FIG. 1b, and assume that the area of phonon flow 104 has a radius that is four times lower than the radius of electron flow 105, then A_{|}/Aₑ is 1/16 which yields from the equation ZT=4.06. Hence we see that for the embodiment illustrated in FIG. 1a and FIG. 1b that the figure of merit ZT for the thermoelectric performance can be approximately four times higher than for traditional devices. Without limitation, more complex thermoelectric materials may substitute for Bi₂Te₃. One example of a complex thermoelectric material is a super-lattice, which is a thermoelectric film comprised of multiple very thin films, the borders of which reduce the lattice thermal conduction. Other examples of complex thermoelectric materials include clathrates and chalcogenides. A comprehensive review of complex thermoelectric materials is provided in Complex Thermoelectric Materials, by G. Jeffrey Snyder and Eric S. Tober, Nature Materials, Vol. 7, February 2008.

FIG. 2a and FIG. 2b show a variation on the embodiment of FIG. 1a and FIG. 1b where four separators 108 are placed between the electrodes in each of the four corners. Only two of these separators are shown because FIG. 2a is a profile view. These separators may be made of glass or other dielectric material preferably with low thermal and electrical conductivity. The height of separators 108 is selected such that as the upper electrode heats up, the thermal expansion differences the silicon and the metals cause the upper electrode to flatten, ultimately forming a gap in the center, as the corner separators become the supports. If the gap of FIG. 2a is controlled to create a 1 nm or less vacuum layer between the two electrodes, then the contact area illustrated by 104 in FIG. 1b is eliminated, and all phonon flow is blocked. However, electrons are able to tunnel in area 105. In this case, A_{|}=0 and the formula for ZT

ZT=α²TAₑ/[ρ(κₑAₑ+κ_{|}A_{|})]

yields a ZT of 5.07 for the material parameters quantified above for Bi₂Te₃ and at room temperature.

The ZT calculations for the invention presented thus far assume the characteristics of the thermoelectric material Bi₂Te₃ that is widely used today for traditional thermoelectric devices. In the case of the embodiment illustrated in FIG. 2a and FIG. 2b, the lattice thermal conductivity of the thermoelectric material is irrelevant because the vacuum gap area 105 prevents all phonon flow. The center contact approach illustrated in FIG. 1a and FIG. 1b prevents most of the phonon flow. For these reasons, the optimal thermoelectric material for the invention might not be Bi₂Te₃, which has evolved as the optimum for traditional devices. Including those materials that have large or larger lattice thermal conductivity can enlarge the space of candidate materials for the invention device. These new material possibilities are important for many reasons. Elements in the periodic table with low lattice thermal conductivity are those with relatively large atomic weights. Semiconductors and metals with relatively large atomic weights tend have the following undesirable properties: (1) toxicity, (2) radioactive, (3) high cost, (4) scarcity in either natural or man-made forms, and (5) inability to withstand higher temperatures.

For example, toxicity is a major concern for traditional thermoelectric materials. Tellurium and similar elements like Antimony that are used in traditional devices are toxic. Silicon and Germanium are semiconductors that are non-toxic, plentiful, and inexpensive, Silicon and Germanium are not used in traditional thermoelectric devices, however, because their lattice thermal conductivities are several times higher than Tellurium and Antimony. Silicon and Germanium would work just fine in the embodiment of FIG. 2a and FIG. 2b because lattice thermal conduction is minimized by the vacuum gap.

Also, in order for thermoelectric devices to be used in power generation, the desire is great to operate them at high temperatures. The laws of thermodynamics state that the higher the temperature delta in an engine, the higher the efficiency of that engine. Very high temperatures, approaching 1000 Kelvin are required to maintain high efficiency power generators, and these temperatures are routinely used in power plant engines fueled by coal, gas, or nuclear energy. Thermoelectric devices need to sustain these same temperatures in order to compete with existing power plants. Bismuth, Tellurium, and Antimony have melting points of 555K, 723K, and 904K respectively. Because of these low melting points, the operational temperature of traditional thermoelectric devices has been limited to 500K. If the hot side of the device is 500K and the cold side is cooled to room temperature. or 300K, then the theoretical maximum efficiency is 40%, and that assumes an infinite ZT. However, silicon and germanium have melting points of 1693K and 1211K, and hence can sustain the temperatures of up to 1000K required to compete with existing power plants in thermodynamic efficiency. For details of thermoelectric performance of silicon-germanium, see Thermal and electrical properties of Czochralski grown GeSi single crystals, by I. Yonenaga et. al. Journal of Physics and Chemistry of Solids 2001. For details about the surface behavior of these materials, see “Selective Epitaxial Growth of SiGe on a SOI Substrate by Using Ultra-High-Vacuum Chemical Vapor Deposition”, by H. Choi, J. Bae, D. Soh, and S. Hong, Journal of the Korean Physical Society, Vol. 48, No. 4, April 2006, pp. 648-652 and “Strain relaxation of SiGe islands on compliant oxide”, by H. Yin et. al. Journal of Applied Physics, vol. 91, number 12, 15 Jun. 2002.

Another advantage of the invention is the ability to operate over a range of temperatures. For traditional thermoelectric devices, Bi₂Te₃ and similar materials are used at low temperatures (lower lattice thermal conductivity, but lower melting points) and other materials like SiGe are used at higher temperatures (higher lattice thermal conductivity but higher melting points). The present invention allows a material such as SiGe to be used at the full range of temperatures because lattice thermal conduction is partially or totally eliminated by the vacuum gap illustrated in FIG. 1a and FIG. 1b and FIG. 2a and FIG. 2b.

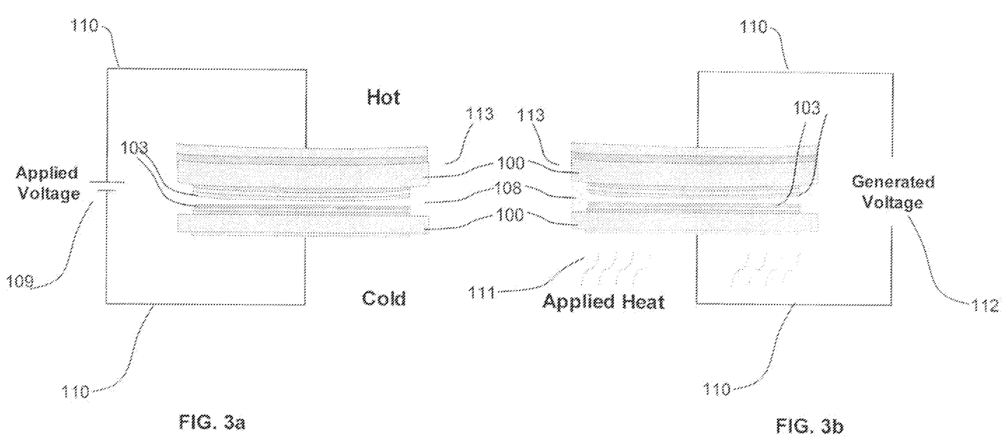

Thermoelectric devices are generally reversible, meaning that a current flow through the device will produce refrigeration and, conversely, applying heat to one side will produce a voltage. The device of this invention is also reversible, and FIG. 3a and FIG. 3b show the preferred configuration for each of the two modes of operation. FIG. 3a shows the preferred configuration for refrigeration, and FIG. 3b shows the preferred configuration for power generation from heat.

In FIG. 3a, the curved bimetallic electrode 113 with the thick copper layer is the hot side. A voltage source 109 supplies a voltage to the top and bottom of the device through wires 110. This voltage produces a current flow through the thermoelectric material in the center of the device, and this current flow moves heat from the bottom electrode to the top electrode assuming that the thermoelectric material used is n-type. Without limitation, a similar diagram could be made with current flowing oppositely by reversing the applied voltage 109, and with a p-type material, the heat would still flow from the bottom electrode to the top electrode.

When the device of FIG. 3a is turned off, the voltage 109 is zero, and central contact exists between the two electrodes. The flow of current moves heat to the top electrode, increasing its temperature. This increased temperature causes the top electrode to flatten out which eventually creates a gap in the center and the top electrode now uses the corner separators for support. The gap in the center will increase in size until it reaches an equilibrium value. If a disturbance causes the gap to become larger than the equilibrium value, then less current will flow because the gap is opening the circuit between the two electrodes. Less current means less heat is moved to the upper electrode, lowering its temperature, and bending back toward the bottom electrode until the equilibrium is re-established. Conversely, if a disturbance causes the gap to be smaller than its equilibrium value, then more current will flow, moving more heat, increasing the temperature of the top electrode, and bending it away from the bottom electrode until again the equilibrium is re-established.

The device of FIG. 3a can be applied to thermoelectric cooling methods, also called the Peltier effect, by choosing active layer 103 to be a thermoelectrically sensitive material. Bimuth Telluride, Antimony Bismuth Telluride, Lead Telluride, Silicon Germanium, and many other materials are known to exhibit the thermoelectric effect, without limitation. In the case of thermoelectric methods applied to the device of FIG. 3a, the gap can be barrier-free, meaning that electrons do need higher than average energy to traverse the gap. The quantum barrier of the bandgap of the thermoelectric material 103 already filters higher energy electrons which enables heat to be moved. So, in this case, the nanometer gap between the two active layers 103 merely needs to interrupt the lattice thermal conduction. The device of FIG. 3a can also be applied to thermo-tunneling cooling methods by choosing active layer 103 to be a low work function material. Examples of low work function materials are Cesium, Barium, Strontium and their oxides. The layer 103 could take the form of a monolayer, sub-monolayer, multiple monolayers, or deposited film. In the case of thermo-tunneling methods applied to the device of FIG. 3a, the gap length does introduce a barrier over which only higher energy electrons can traverse. In thermo-tunneling applications, the nanometer gap serves as both the quantum barrier to filter electrons and also as an interruption of the lattice thermal conduction.

In the preferred configuration for power generation in FIG. 3b, note that the curved, bimetallic electrode is now the cold side. Heat is applied to the flat electrode from a heat source 111. Because the temperature of the heat source might vary during operation, as in a concentrated solar application for example, it is preferable to apply the heat to the side that would not vary the gap from its optimal value. As is typical in thermoelectric devices, the heat source ill creates a temperature gradient within the thermoelectrically sensitive material, which in turn creates a voltage that can be brought to an electrical circuit needing power 112 through wires 110.

When no heat is applied at heat source 111, center contact exists between the two electrodes. As the heat source is turned on, some of this heat will flow through the center contact, increasing the temperature of the top electrode 113. The increased temperature causes the top electrode 113 to flatten out, ultimately creating a gap in the center as the top electrode then rests on the corner separators 108. As in the case for refrigeration, an equilibrium gap is formed. If a disturbance causes the gap to become larger than equilibrium, then the top electrode will cool down because of less heat traversing the gap, which causes the top electrode 113 to bend toward the bottom electrode, and re-establish the equilibrium. If a disturbance causes the gap to become smaller than equilibrium, then the increased heat conduction in the center will increase the temperature of the top electrode, causing it to bend away in the center until the equilibrium gap is re-established.

The device of FIG. 3b may be applied to thermoelectric power generation effects, also called the Seebeck effect, by choosing active layer material 103 to be a thermoelectrically sensitive material. Again, without limitation, the same materials mentioned earlier that exhibit the Peltier effect also exhibit the Seebeck effect. The device of FIG. 3b may also be applied to thermo-tunneling power generation by choosing the active layer 103 to be a low work function material. Without limitation, the same materials useful for thermo-tunneling cooling are also useful for thermo-tunneling power generation. The device of FIG. 3b may also be applied to thermo-photovoltaic methods by choosing lower active layer material 103 to be photo-emissive and the upper layer 103 to be photosensitive. Photo-emissive materials emit photons in response to the application of heat. Photosensitive materials generate electricity upon the receipt of photons. Photons are also capable of tunneling across a vacuum gap such as the one illustrated in FIG. 3b, thereby converting heat to electricity while retaining thermal isolation. The required gap length for photon tunneling is typically much less than the wavelength. For visible light, the wavelength is 400 to 700 nanometers, so a gap length of 1 nm to 200 nm is sufficiently small for effective photon tunneling. Without limitation, examples of photo-emissive materials are tungsten and titanium. Also without limitation, examples of photosensitive materials include photovoltaic materials such as silicon, germanium, tellurium, cadmium and combinations of these. For a summary of thermo-photovoltaic methods, see Micron-gap ThermoPhoto Voltaics (MTPV), by R. DiMatteo et al, Thermophotovoltaic Generation of Electricity, American Institute of Physics, 2004.

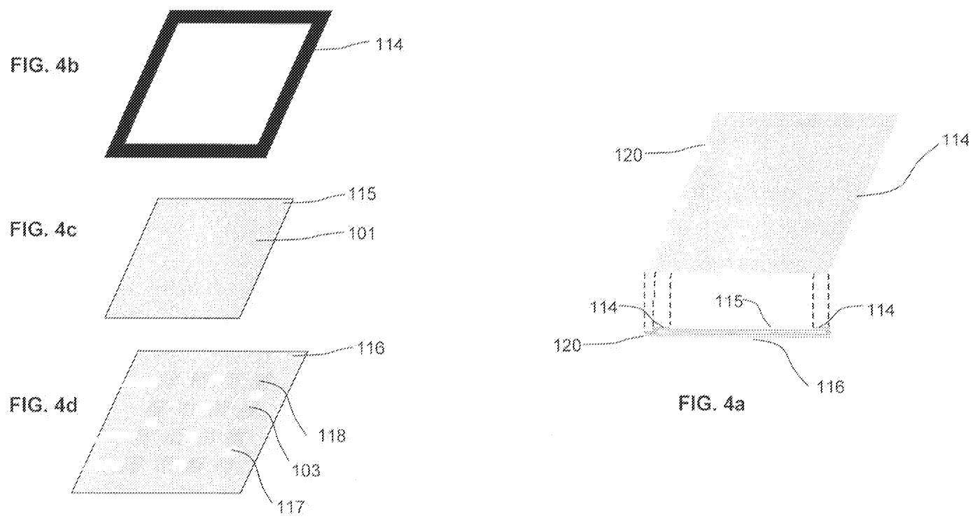

The previous figures FIG. 1 through FIG. 3 showed the preferred embodiments for a single thermoelectric junction. FIG. 4a to FIG. 4d show how a plurality of junctions can be fabricated using standard silicon substrates with deposited metal films, with the hot and cold sides vacuum-sealed together using standard wafer bonding processes and equipment.

FIG. 4a shows how the top substrate 115 comes together with bottom substrate 116 with glass frame 114 in between. These three components 115, 116, and 114 also comprise the walls of the vacuum chamber. The top 115 and bottom 116 are each attached to the glass frame 114 using glass frit or other vacuum sealing adhesives along the overlapping perimeter. The bottom substrate 116 extends out beyond the glass frame and beyond the vacuum seal in order to expose electrical connections 120. These electrical connections allow the device to be connected to an electrical power supply for refrigeration or to an electrical load for power generation. Bottom silicon substrate 116 in FIG. 4d serves as the carrier for the thermoelectric stacks 118 and 203 and associated interconnect circuitry 117. Note how, in contrast with FIG. 1a and FIG. 1b and FIG. 2a and FIG. 2b, the electrical current does not need to flow through the silicon substrate in FIG. 4a and FIG. 4b. The silicon substrate used in this embodiment of FIG. 4a and FIG. 4b is un-doped or lightly doped to prevent the silicon from becoming short circuits. This substrate 116 in FIG. 4d also serves as the bottom of the vacuum package. The top silicon substrate 115 in FIG. 4c is has thick metal pads 101. These pads are deposited or adhered to the silicon substrate 115 at a high temperature so that at room temperature and at operating temperatures, a local curvature exists caused by bimetallic stresses between thick metal 101 and silicon substrate 115. The top substrate also has thermoelectric stacks, which face the thermoelectric stacks of the bottom substrate 103 and 118 in FIG. 4d. The thermoelectric stacks for the top substrate are not visible in FIG. 4c. The primary function of the glass frame 114 in FIG. 4b is to minimize the heat conduction between the hot and cold sides, as glass has a much lower thermal conductivity than silicon. A direct face-to-face perimeter bond of the top and bottom silicon substrates would have high thermal conduction, decreasing performance. The side width of the glass frame 114 in FIG. 4b can be selected to achieve the desired amount of thermal isolation.

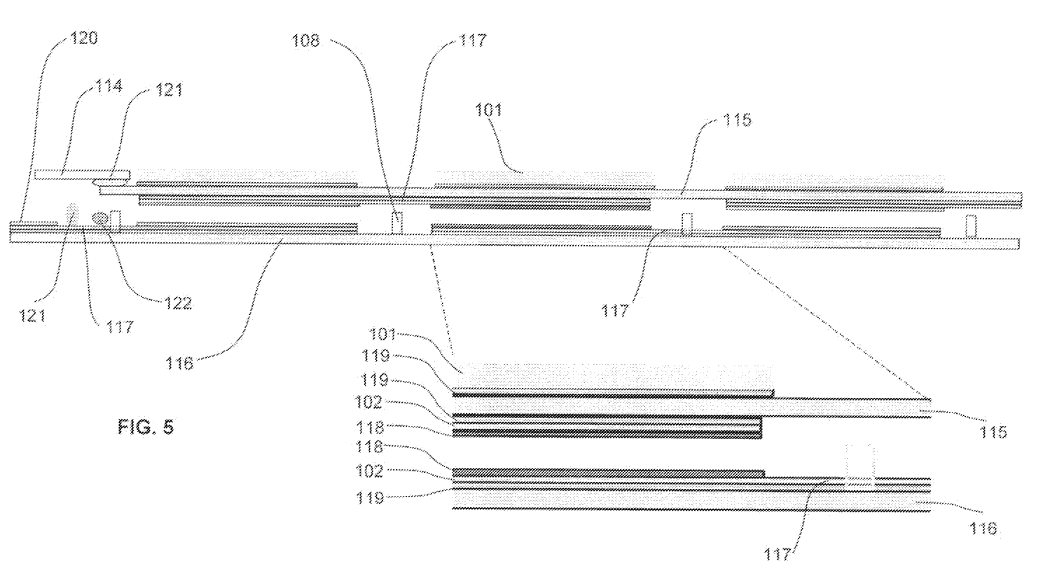

FIG. 5a shows a profile view of the device of FIG. 4 including detail about the film stack. The inset in FIG. 5b is a blow-up view of FIG. 5a. Glass frame 114 is bonded and vacuum-sealed to the top substrate 115 using perimeter sealant 121, which might be glass frit, solder, compression bond, or other suitable material. A similar perimeter sealant 121 bonds the glass frame 114 to the bottom substrate. Pad 120 is externally exposed for electrical connection purposes. Getter 122 is positioned within the vacuum cavity to react with any residual, out-gassed, or leaked-in gases during the life of the device, helping to maintain close to ideal vacuum conditions. Electrical traces 117 connect the thermoelectric pads to each other and to the external pads. Optional glass posts 108 serve as corner separators for each thermoelectric stack during operation when a gap is formed. When the device is turned off, the center contact of the thermoelectric stacks provide support against the vacuum pressure pulling the top and bottom electrodes together. Film 101 is a thick film with a thermal expansion coefficient that is higher than for the substrate 115. This film 101 is deposited or bonded to substrate 115 at an elevated temperature for reasons described earlier. Copper, aluminum, tin, and many other metals and alloys are appropriate for film 101. Film 119 is a thin layer of another metal such as titanium, tungsten, or other alloy that provides good adhesion between the thick film 101 and the substrate 115. Without limitation, other adhesion layers are known to the art.

The films deposited on the interior portion of the device will now be described. Adhesion layer 102 provides good adhesion between substrate 115 or 116 and the film 102, which has high electrical conductivity. Film 102 carries most of the electrical current from one thermoelectric stack to the next and to the external connections. Film 118 is the thermoelectrically active layer, which may be a semiconductor, an oxide, or a low work function material, photosensitive or photo-emissive layer as previously described.

Because low voltage and high current characterize thermoelectric junctions, most thermoelectric devices internally connect the junctions in series. By having many series connected junctions, the available supply or load voltage can better match a sum of individual junction voltages. These series connections mean that the heat must flow with the current in the p-type junctions and against the current in the n-type junctions.

The preferred material for thermoelectric film 103 of FIG. 4d is in cooling configurations Bismuth Telluride for the n-type stacks and Antimony Bismuth Telluride for the p-type stacks. Film 118 in FIG. 4d and FIG. 5b show an example of how the p-type material if used in contrast with the n-type material 103. For power generation operation, the preferred material for film 103 and 118 is Silicon Germanium, each with differing compositions. Without limitation, the material for film 103 can also be a super-lattice thermoelectric material, a quantum well, appropriately doped semiconductor, or other thermoelectric material.

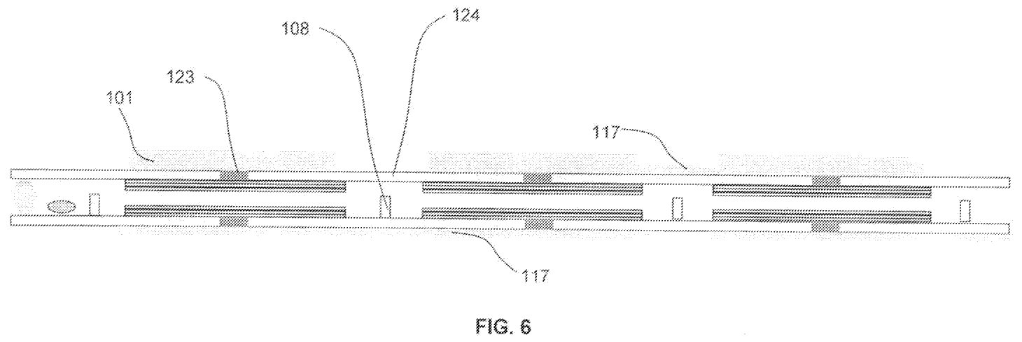

FIG. 6 shows an alternative embodiment to the device of FIG. 4a and FIG. 4b and FIG, 5a and FIG. 5b. Glass 124 is used as both the top and bottom substrates. Because glass has much lower thermal conductivity (1 watt/meter-degree) as compared to silicon (150 watts/meter-degree), another means is useful to conduct heat away from the thermoelectric junctions to the outside. Metal inserts 123 in the glass substrates 124 provide this means, and a highly thermal conducting path now exists from the thermoelectric junction to the outside, Metal inserts 123 also optionally provide an electrical path to connect the thermoelectric junctions together using metal traces 117. These metal traces may be located on the inside or the outside of the vacuum cavity defined by the substrate top and bottom. The thick metal pads 101 provide the bimetallic arrangement and produce curvature as before. The remainder of the parts and operation of the device of FIG. 6 is evident from the very similar diagram in FIG. 4a and FIG. 4b and FIG. 5a and FIG. 5b.

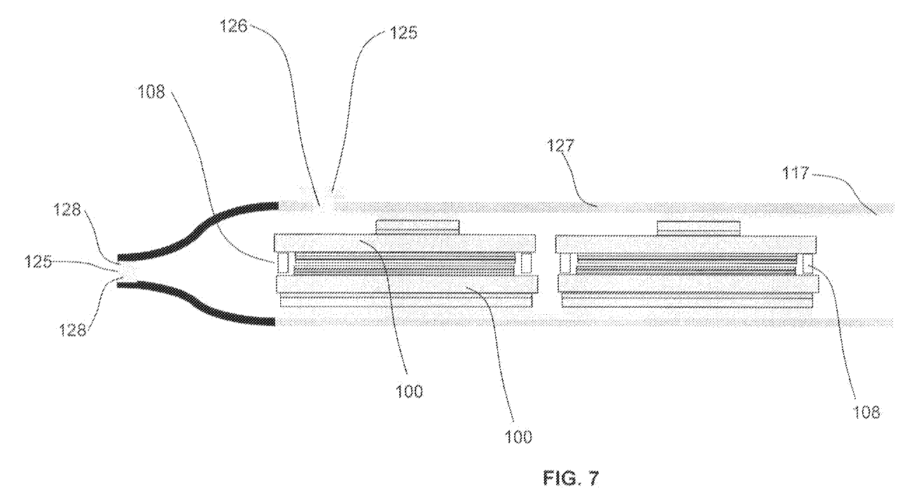

FIG. 7 shows another alternative embodiment to the device of FIG. 4a and FIG. 4b and FIG. 5a and FIG. 5b using a flexible plastic vacuum wall 127. Flexible plastic materials like polyimide and Kapton are known to be very low out-gassing and hence compatible with vacuum environments. In FIG. 7, silicon substrates 100, optional glass posts 108, and bimetallic arrangements are used as before. The polyimide vacuum walls 127 have electrical traces 117 that provide the connections between the thermoelectric stacks and to the external connections using a through-hole 126 and a solder pad 125 for easy electrical connection to wires. A vacuum seal 125 is provided around the perimeter. One way to achieve this perimeter vacuum seal is to place a copper or similar metal trace 128 and use solder 125 as the sealant. Without limitation, other sealing techniques may also be applied. Polyimide is known to be porous, and a thin layer of non-porous material such as a metal film or silicon dioxide or other film may be required (not shown).

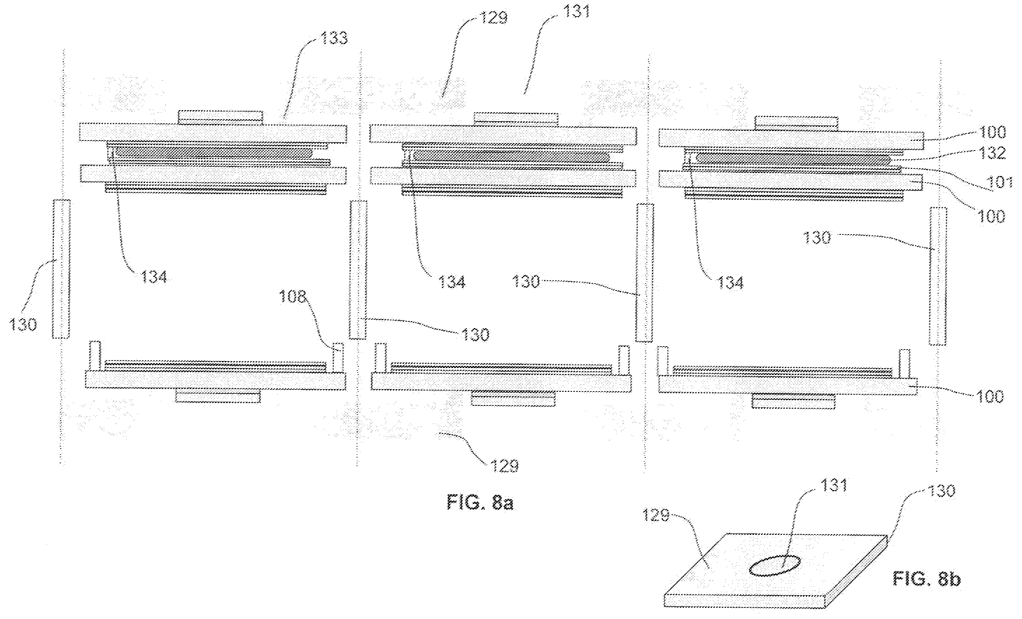

The embodiments shown in FIG. 4 through FIG. 7 all use a flexible material as the vacuum wall. For some implementations, particularly in harsh environments, a rigid package might be desired or required. FIG. 8a and FIG. 8b show an alternative embodiment where the vacuum walls are rigid glass substrates 129. Rigid silicon substrates 100 are exposed by holes 131 in the glass to provide electrical and thermal connections to the outside. In the fabrication of the device of FIG. 8a and FIG. 8b, the upper and lower substrates 129 start as glass wafers with holes 131. These substrates serve as the top and bottom of the vacuum cavity, except in the holes 131 wherein silicon substrates 100 are vacuum-sealed around the perimeter of these holes. A glass lattice 130 is inserted between the upper and lower substrates and is perimeter-bonded with a vacuum seal. The bimetal configuration is achieved by the middle silicon die 100 in combination with its thick metal layer 101 and is electrically connected to the rigid silicon die by a metal bump 134. Flexible thermal interface layer 132 is placed between the flexible silicon die and the rigid silicon die to allow heat to flow while permitting compliance during the flexing. Thermal interface layer 132 may be, without limitation, graphite. Optional glass posts 108 serve the same function as before. The dotted lines in FIG. 8a are cut lines showing where individual devices are cut out using a wafer saw, ultrasonic saw, laser ablator, or similar machine. FIG. 8b shows one final package once it has been cut out. The entire outside of the package is rigid glass except for metals exposed by through holes 131. These metals are deposited on rigid silicon substrates. Note that the top and bottom of FIG. 8b originated from the top and bottom silicon substrate wafers 129 in FIG. 8a, and that the sidewalls of FIG. 8b are halves of the glass lattice 130 inserted between these same glass substrate wafers.

From the previous discussion, the following is the formula for figure of merit ZT.

ZT=α²TAₑ/[ρ(κₑAₑ+κ_{|}A_{|})]

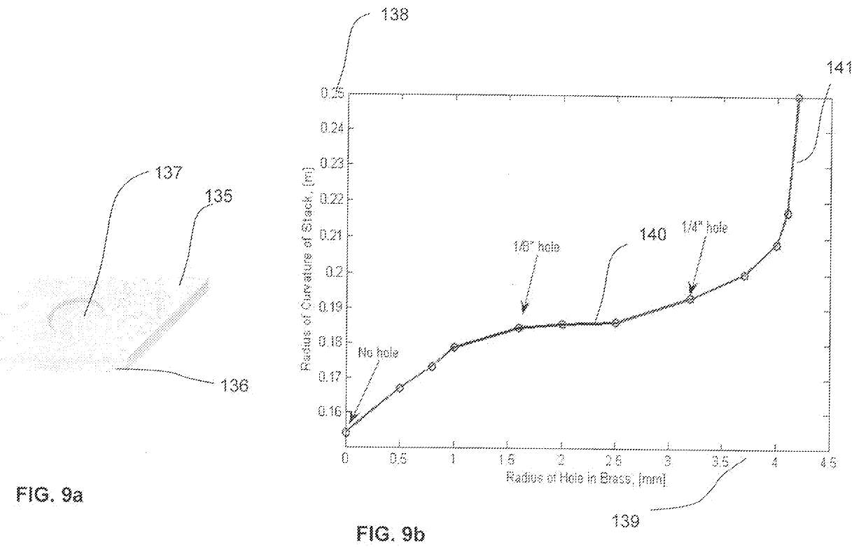

It is evident that a higher electron tunneling area Aₑ relative to the phonon tunneling or contact area A_{|} benefits equates to a higher ZT and improves the device performance. In the previous embodiments illustrated in FIG. 1 through FIG. 8, the areas Aₑ and A_{|} were determined by the curvature of the bimetal, which in turn is a function of the properties of the materials used for the substrate and the thick metal film and the geometry (thickness and width). FIG. 9a illustrates an arrangement for decreasing the curvature further while not changing the materials used or the dimensions of the electrodes. The metal layer in the center area of the bimetal thick film 135 is either removed, not deposited, or deposited with much less thickness on substrate 136, leaving a void located at 137. The end result is a device with a less curvature in the center, or equivalently a higher radius of curvature in the center. FIG. 9b shows a graph with radius of curvature on the Y-axis 138, and radius of the hole 137 on the X-axis 139. The values on the graph 140 were generated by computer simulation using ANSYS software. As indicated by the graph, the radius of curvature of the bimetal in the center increases as the diameter of the hole increases. In this simulation, the lateral dimension of the square bimetal structure in FIG. 9a was 10 millimeters. As the radius of the hole increases toward half of the width of the bimetal, the radius of curvature in the center 141 increases without bound, indicating that very low center curvatures can be achieved with this approach.

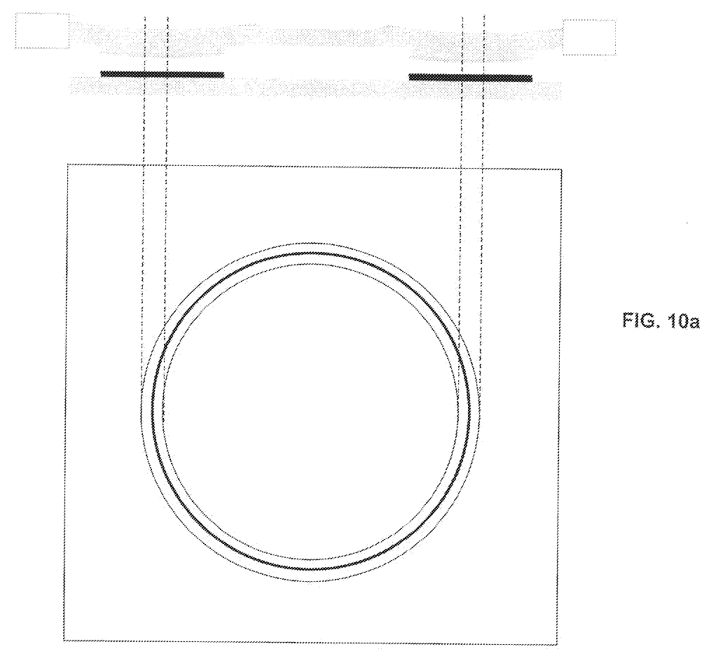

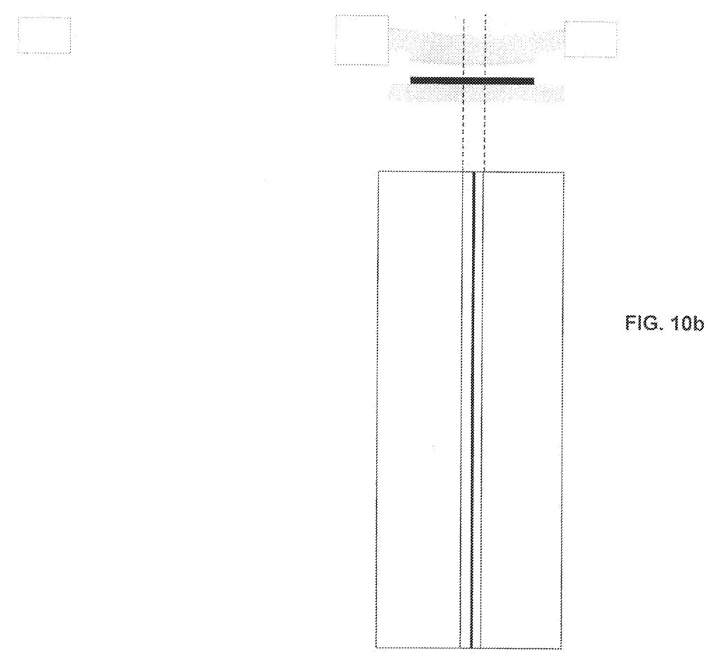

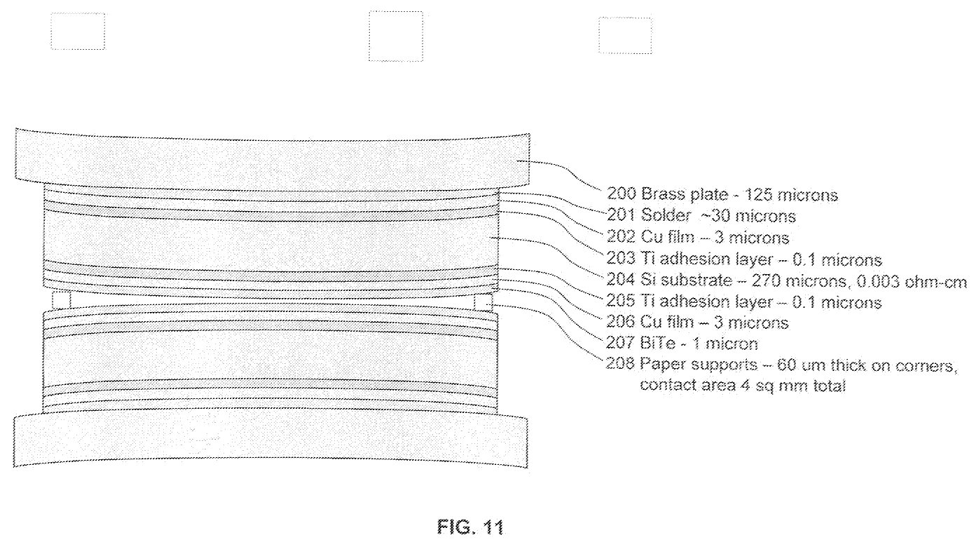

FIG. 10a and FIG. 10b show other analogous geometries for achieving a local contact area surrounded by a tunneling area. In FIG. 10a, the tunneling area is an annular ring around a thinner annular ring in contact. In FIG. 10b, the tunneling area is a linear stripe surrounding a thinner stripe in contact. Much other analogous geometries are possible that apply the same concept illustrated in FIG. 1a and FIG. 1b and FIG. 2a and FIG. 2b.

### Experimental Results

FIG. 11 illustrates an apparatus very similar to FIG. 2a that was built to test the concept of this invention. Each electrode was 1 square centimeter. The bimetal arrangement consisted of a brass plate 200 that was 125 microns thick and was soldered to a silicon die 204 that was 270 microns thick. The corner separators 208 were made of paper 60 microns in thickness and each one consisted of about 1 square millimeter of corner contact area. The thermoelectric layer was formed by depositing 10 nanometers of Bismuth, followed by 15 nanometers of Tellurium repetitively until the total thickness of 1 micron was achieved. Copper films 202 and 206 were 3.0 microns thick and served as current spreaders, allowing current to be conducted through the entire area of the silicon die 204. Titanium adhesion layers 203 and 205 were placed between the copper and the silicon on both top and bottom of silicon die 204. All layers on the silicon die 204 were sequentially deposited using thermal evaporation from pure element sources in an electron beam evaporation system maintained at high vacuum pressure. After fabrication, the finished electrodes were baked at 200 degrees centigrade for about 1 hour to anneal the Bi₂Te₃ film. The bottom electrode was fabricated identically to the top electrode, only positioned upside down as shown in FIG. 11.

The entire electrode pair illustrated in FIG. 11 was placed between spring-loaded electrical connectors in a vacuum bell jar. A voltage from a DC power supply was applied to the spring-loaded connectors. A voltmeter permitted reading the voltage right at the brass plates, and two small thermocouples permitted reading the temperature on each brass plate. The current flow through the device was read from a meter on the power supply.

During the experiment, the applied voltage was increased gradually, and the voltage, current, and temperature of each electrode were measured at several data points. As the supply voltage increased, the current increased, and the electrical resistance of the device caused both electrodes to heat up. As the electrode pair heated up to approximately 50 degrees centigrade, a nanometer gap started to form.

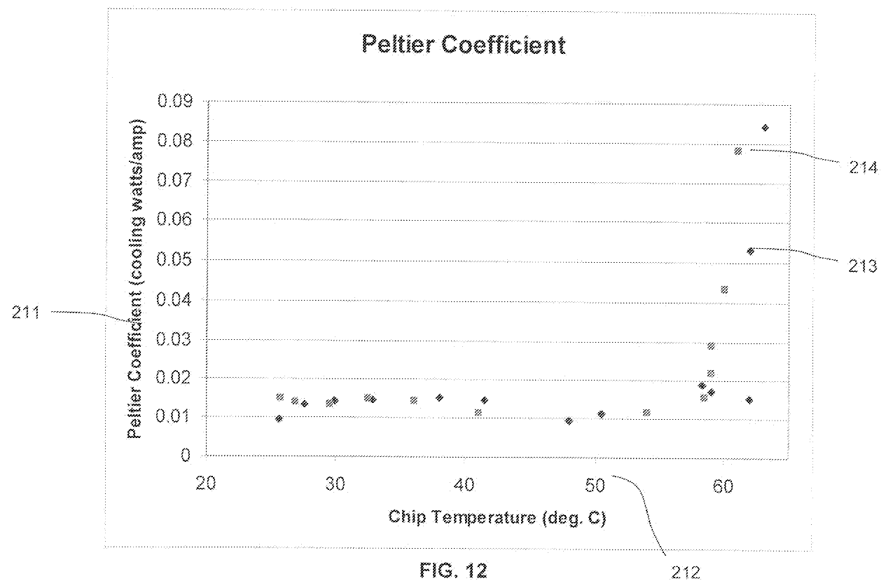

FIG. 12 illustrates that a nanometer gap formed and that the thermoelectric effect was enhanced by the formation of the nanometer vacuum gap. In FIG. 12, the Peltier coefficient axis 211 was indicated for several readings of the average electrode temperature axis 212. The Peltier coefficient is proportional to the Seebeck coefficient. As the device heats up to approximately 57 degrees centigrade, the gap begins to form and the Peltier coefficient rises rapidly providing evidence of the advantage of this invention's gap forming means. The round data points 213 indicate current flow in the opposite direction as the square data points 214. The ZT for this experiment was estimated to be 0.2.

Many limitations in the apparatus used for these measurements prevented the demonstration of a ZT that is better than the state of the art ZT of 1.04. The non-uniform stoichiometry of the film deposition process caused inferior Peltier and Seebeck coefficients prior to gap formation. The expected Peltier coefficient value for Bi₂Te₃ is about 0.06 watts/amp. The value measured in this experiment for without the gap was about 0.015 watts/amp. The lower measured value is likely due to the non-uniform stoichiometry from the alternating layers, as the Peltier coefficient is strongly dependent on correct stoichiometry for this material. The surface roughness was much greater than the required 1 nanometer. The curvature of the soldered brass plate onto the silicon die is much greater than what would be possible with hot-substrate deposition in a semiconductor foundry. Finally, the paper spacers introduced much greater thermal backflow than would the glass separators in the preferred embodiment. The glass separators can be fabricated with semiconductor processing to be 25 microns laterally instead of the 1000 microns for the paper spacers used in this experiment. Without these limitations, a significant improvement over the state of the art ZT would have been expected.

Multiples units of this device can be connected together in parallel and in series in order to achieve higher levels of energy conversion or to match voltages with the power supply or electrical load.

It should be emphasized that the above-described embodiments of the present device and process, particularly, and “preferred” embodiments, are merely possible examples of implementations and merely set forth for a clear understanding of the principles of the invention. Many different embodiments of the tunneling and self-positioning electrode device described herein may be designed and/or fabricated without departing from the spirit and scope of the invention. All such modifications and variations are intended to be included herein within the scope of this disclosure and protected by the following claims. Therefore the scope of the invention is not intended to be limited except as indicated in the appended claims.

I claim:

1. A device comprising first and second electrodes or electrode assemblies having facing surfaces wherein at least one of the electrodes or electrode assemblies has one electrode facing surface curves away from the other electrode facing surface by a distance that permits electron or photon tunneling.

2. The device of claim 1, wherein the distance is: (a) less than 1.0 nanometers permitting barrier-free electron tunneling from a surface with a high work function; or (b) is between 1.0 and 10.0 nanometers permitting electron thermo-tunneling from an electrode surface with a low work function; or (c) is between 1.0 and 200 nanometers permitting photon tunneling.

3. The device of claim 1, wherein a semiconductor material is deposited on the facing surfaces of the electrodes, wherein the semiconductor material preferably comprises a thermoelectric material, more preferably a material selected from the group consisting of: bismuth telluride, antimony bismuth telluride, lead telluride, silicon germanium, thallium, a clathrate, a chalcogenide, or a superlattice of alternating layers.

4. The device of claim 2(b), wherein the low work function surface is selected from the group consisting of: Cesium, Barium, Strontium or oxides of any of these.

5. The device of claim 2(c), wherein one of the electrodes is photosensitive and the other is photo-emissive, wherein the photosensitive material preferably is a photovoltaic material, more preferably a photosensitive material selected from the group consisting of silicon, germanium, tellurium, cadmium and a combination or mixture thereof, and wherein the photo-emissive material preferably is selected from tungsten, titanium, and a mixture thereof.

6. The device of claim 1, wherein portions of the first and second electrodes are in contact with one another.

7. The device of claim 6, wherein the first and second electrodes form a contact area having a center with one or both electrodes curving away from the center area, more preferably a circular contact area with one or both electrodes curving away in an area forming an annular ring surrounding the circle, or a contact area in the form of a line with one or both electrodes curving away in a rectangular area surrounding the line.

8. The device of claim 1, wherein the curved surface is formed by bonding two layers together having differing coefficients of thermal expansion at a temperature different from the planned operating temperature.

9. The device of claim 8, wherein one layer is glass or a single crystal semiconductor, preferably selected from the group consisting of silicon, germanium, silicon carbide, and gallium arsenide, and the other is a metal or metal alloy.

10. The device of claim 8, including separators, preferably formed of glass, outside the tunneling area for supporting the two electrodes.

11. The device of claim 10, wherein the separators support the two electrodes when an elevated temperature is reached, eliminating the contact area but retaining the tunneling area, wherein the elevated temperature preferably is produced by Peltier-effect heat transfer, electrical resistance, photon absorption, or a combination thereof, or by heat conduction in the contact area prior to its elimination, said heat originating from a heat source producing electricity from the Seebeck effect, thermo-tunneling effect, or thermo-photovoltaic effect.

12. A plurality of devices as claimed in claim 1, wherein one set of electrodes is layered on a common substrate and the corresponding facing electrodes are layered on another common substrate.

13. The device of claim 12, in a vacuum enclosure.

14. The device of claim 12, including a frame wherein one substrate is bonded and sealed to the inner perimeter of the frame and the facing substrate is bonded and sealed to the outer perimeter of the frame, wherein the frame preferably is formed of a material with low thermal conductivity, more preferably glass, which glass preferably is altered with impurities to match its thermal expansion coefficient with the substrate material.

15. The device of claim 14, wherein the bonding and sealing takes place in a vacuum chamber, leaving the interior of the device evacuated when removed from the chamber.

16. The device of claim 12, wherein the substrates are formed from flexible glass, said optionally further including inserts with high thermal and electrical conductivity placed at or near the tunneling areas, wherein the inserts preferably have a thermal expansion coefficient that substantially matches that of the glass substrates, and more preferably are formed of tungsten.

17. The device of claim 13, wherein the vacuum enclosure is rigid glass with holes exposing electrical and thermal paths, and optionally further including silicon die substrates bonded and sealed to the inside surface perimeter of the holes.

18. The device of claim 14, wherein the bonding and sealing material is glass frit.

19. The device of claim 14, wherein the bonding and sealing is anodic, or is formed by compression.

20. The device of claim 12, wherein the vacuum enclosure comprises a resiliently flexible plastic that is vacuum compatible or is coated with a non-porous vacuum compatible film, preferably a polyimide, and including metal traces (a) to electrically connect the electrodes together, (b) to connect to an external power supply or electrical load, and/or (c) to serve as pads for a vacuum seal comprising solder of any combination of these.

21. The device of claim 12, including a getter, preferably is selected from the group consisting of: Titanium, Cesium, Barium, Potassium, Sodium and a combination of two or more thereof.

22. A process for converting heat to electrical energy comprising subjecting the device of claim 1 to a temperature difference.

23. The process of claim 22, wherein the heat source is selected from a radiation source, heat from the environment, geothermal energy, and heat generated from engines or from animal metabolism.

24. The process of claim 23, wherein (a) the source of heat is a living human body; (b) the source of heat is a living human body and the device is a hand held device; (c) wherein the source of heat is selected from a running electrical, steam or internal combustion engine, burning fuel, or their exhaust gases; and (d) wherein the source of heat is selected from an internal combustion engine or its exhaust gases and the device is incorporated in the engine or gas exhaust line as a heat sink.

25. The process of claim 22, operated at naturally occurring temperatures.

26. The process of claim 22, wherein the device is used in a refrigerator, an air conditioner, a cooling blanket, cooling clothing, or a cooling device in contact with or contained within a human or animal body.

27. A device comprising multiple units of the device of claim 1, wherein the electrodes are arranged in multiple layers of periodic spacing.

28. A device comprising multiple units of claim 1, assembled in series or in parallel.
